(19) United States
(12) Patent Application Publication
(10) Pub. No.: US 2005/0040479 A1
(43) Pub. Date: Feb. 24, 2005

(54) Oxide-Nitride-Oxide spacer with oxide layers free of nitridization

(75) Inventors: Viktor Koldiaev, San Jose, CA (US); George Cheroff, Oakland, CA (US)

Correspondence Address: STEPTOE & JOHNSON LLP, 201 EAST WASHINGTON STREET, SUITE 1600, PHOENIX, AZ, 85004, US

(73) Assignee: PDF Solutions

(21) Appl. No.: 10/644,633

(22) Filed: Aug. 20, 2003

(51) Int. Cl. H01L 29/76; H01L 31/062

(52) U.S. Cl. 257/411; 257/412; 257/900

(57) ABSTRACT

A spacer (2) for a MOSFET is provided with an Oxide-Nitride-Oxide structure. The nitride layer (18) has a structure formed through a process that isolates first oxide layer (16) from ammonium precursors that may be used to form nitride layer (18).

### FIELD OF THE INVENTION

The present invention relates to the field of semiconductors, and more particularly to spacer structures that include a nitride layer.

### BACKGROUND OF THE INVENTION

The semiconductor industry is continuously striving to reduce the size and scale of transistors in order to increase the speed and performance of microprocessors, while at the same time driving down the cost. Reductions in the scale of transistors lead to a variety of problems that require new design solutions. For instance, shrinking the size of a Metal Oxide Semiconductor Field Effect Transistor (MOSFET) reduces the distance between the source, gate, and drain, thereby increasing degradation problems resulting from various physical phenomena commonly referred to as short channel effects.

Hot carrier injection is one of the major problems encountered in scaling that is caused by very short channel lengths. It is a phenomenon that results from ballistic carrier transport, whereby electrons traverse the channel between the source and drain while experiencing few, if any, scattering events. This ballistic transport can cause electrons to become injected into the gate oxide causing it to degrade. One design solution that compensates for hot carrier injection is a Lightly Doped Drain (LDD) MOSFET. With an LDD MOSFET, shallow implanted source/drain extensions are formed between the heavily doped source/drain regions and the channel. The reduced doping gradient provided by these shallow implanted extensions lowers the electric field in the vicinity of the drain and shifts the position of the peak electric field toward the end of channel. Carrier injection into the gate dielectric layer is thereby reduced.

LDD MOSFETS are formed using spacers. Spacers are dielectric structures that abut the gate structure of a MOSFET. Spacers function to aid in the fabrication of the shallow implanted source/drain extensions that extend between the channel and the source/drain. In addition, spacers function to electrically pacify the gate structure and insulate it from the source/drain regions. A variety of designs for spacer structures are known today in the technology. Common spacer structures known to the art include an “L” and a “D” configuration. Triangle and trapezoidal configurations are also used to form spacers. The first known method to form a spacer structure used a single layer of silicon dioxide (SiO₂). Currently, other dielectric materials such as silicon nitride (Si₃N₄) and silicon oxynitride (SiON) are used to form spacers, generally in 3-layered structures.

The horizontal length, w, of the spacer at the Si interface determines the length of the LDD region, and significantly affects the device performance parameters, e.g. the value of the parasitic resistance. A key device design parameter is the ratio of the height of the gate stack h that includes the gate dielectric and electrode to the spacer width w. Referring now to FIG. 1, FIG. 1 shows the structure of a PRIOR ART spacer that is fabricated from a single oxide layer, and demonstrates the initial use of a spacer for the creation of an LDD region. Also visible in FIG. 1 are the gate, gate dielectric, and source/drain contact region that are formed on a substrate. With this single oxide layer spacer known to the art, the spacer width, w, is fixed by the height, h, of the gate electrode in the dry etch process since a reduction of the spacer width would entail further etching of the gate electrode. Consequently, with this prior art single oxide layer spacer, it is not possible to vary the spacer width w independently of the height h. Since the width of the LDD regions is determined by the spacer width, w, this restriction does not allow for further scaling of the LDD regions to shorter lengths that can be realized by shallow diffusion techniques. It was therefore desirable to improve upon the single oxide layer spacer known to the art and develop a spacer structure that allowed for variation of the spacer width, w, independent of the spacer height, h.

A three-layer spacer structure known to the art is shown in FIG. 2. This three layer spacer structure was introduced to enable the variation of the spacer width, w, independently of the spacer height, h. This three-layer spacer has an Oxide-Nitride-Oxide (ONO) spacer structure. The three-layer spacer is formed from an initial deposition of a thin oxide layer, followed by a thin silicon nitride (Si₃N₄) layer, and a final layer of a relatively thick oxide. Note that commonly silicon nitride (Si₃N₄) is simply referred to as SiN. The first oxide layer serves to isolate the silicon nitride (Si₃N₄), or “SiN” layer from the Si surface in order to avoid degradation of device properties induced by the stress that arises at SiN/Si interfaces. The second silicon nitride, which possesses a very high etch selectivity ratio with respect to SiO₂, acts as an etch stop in the formation of the spacer. Therefore, due to the inclusion of the nitride layer, the spacer layer width, w, can be determined independent of the stack height, h, by the dry etch time parameters acting on the thick oxide layer.

Despite the advances brought about by the use of SiN in a spacer structure, which allows for a reduction of the width of the LLD region, the existing three-layer process has not addressed the deleterious effects caused by the partial nitridization of the first oxide layer. Currently, the known methods of fabricating spacer structures with nitride layers involve the use of nitride deposition processes, e.g. Low Pressure Chemical Vapor Deposition (LPCVD) or Plasma Enhanced Chemical Vapor Deposition (PECVD), that include ammonium precursors. These ammonium precursors interact with the underlying oxide layer and nitridize the oxide layer, during the so called “incubation time”, i.e. the time during which no Silicon nitride is being deposited. This nitridization of the underlying oxide layer into various forms of oxynitride during the incubation period of the deposition process causes a high stress at the silicon-oxynitride interface. The stressed interface results in the deactivation of acceptors or donors in the source/drain extension regions via a clustering mechanism, thereby causing higher series resistance with the channel in the “on” state. This higher series resistance in the extension regions gives rise to a degradation of the drive current.

It is therefore highly desirable to develop a narrow spacer structure capable of meeting current scaling demands utilizing a silicon nitride layer while avoiding the ill effects caused by nitridization of the underlying oxide layer.

### BRIEF DESCRIPTION OF THE DRAWINGS

FIG. 1 illustrates a cross-section of a PRIOR ART spacer having a single oxide layer.

FIG. 2 illustrates a cross-section of a PRIOR ART spacer having an Oxide-Nitride-Oxide structure.

FIG. 3 illustrates a cross-section of a MOSFET including a spacer structure formed in accordance with a present embodiment of the invention.

FIG. 4 illustrates a cross-section of a spacer stack fabricated in accordance with a preferred embodiment of the present invention.

FIG. 5 illustrates a flow chart depicting a process for fabricating the spacer stack illustrated in FIG. 4.

FIG. 6 illustrates a cross-section of a spacer stack fabricated in accordance with an alternative embodiment of the present invention.

FIG. 7 illustrates a flow chart depicting a process for fabricating the spacer stack illustrated in FIG. 6.

FIG. 8 illustrates a cross-section of a spacer stack fabricated in accordance with an alternative embodiment of the present invention.

FIG. 9 illustrates a flow chart depicting a process for fabricating the spacer stack illustrated in FIG. 8.

FIG. 10 illustrates a cross-section of a spacer stack fabricated in accordance with an alternative embodiment of the present invention.

FIG. 11 illustrates a flow chart depicting a process for fabricating the spacer stack illustrated in FIG. 10.

FIGS. 12-16 illustrate a series of diagrams depicting a preferred process for fabricating a spacer in accordance with a present preferred embodiment of the invention.

FIG. 12 illustrates a diagram of a semiconductor wafer having a gate structure in accordance with a preferred embodiment of the present invention.

FIG. 13 illustrates a diagram of a semiconductor wafer having a first spacer oxide layer deposited in accordance with a present preferred embodiment of the invention.

FIG. 14 illustrates a diagram of a semiconductor wafer having a silicon nitride layer deposited over a first spacer oxide layer in accordance with a present embodiment of the invention.

FIG. 15 illustrates a diagram of a semiconductor wafer having a second spacer oxide layer deposited over a silicon nitride (Si₃N₄) layer in accordance with a present preferred embodiment of the invention.

FIG. 16 illustrates a diagram of a cross-section of a semiconductor wafer having a spacer formed in accordance with a present preferred embodiment of the invention.

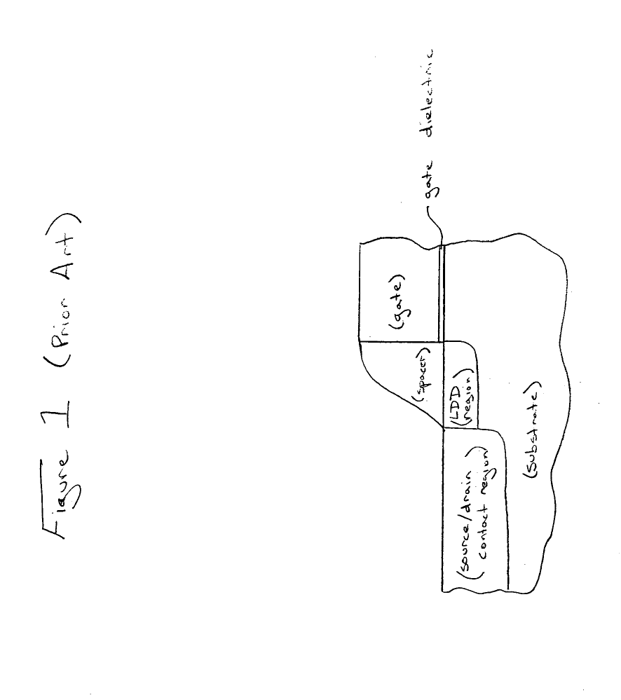

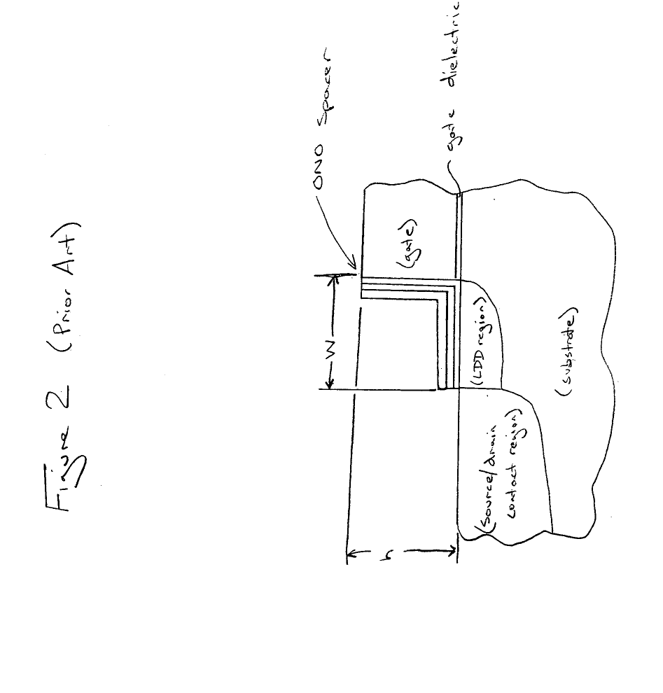

### DETAILED DESCRIPTION OF PREFERRED EMBODIMENTS

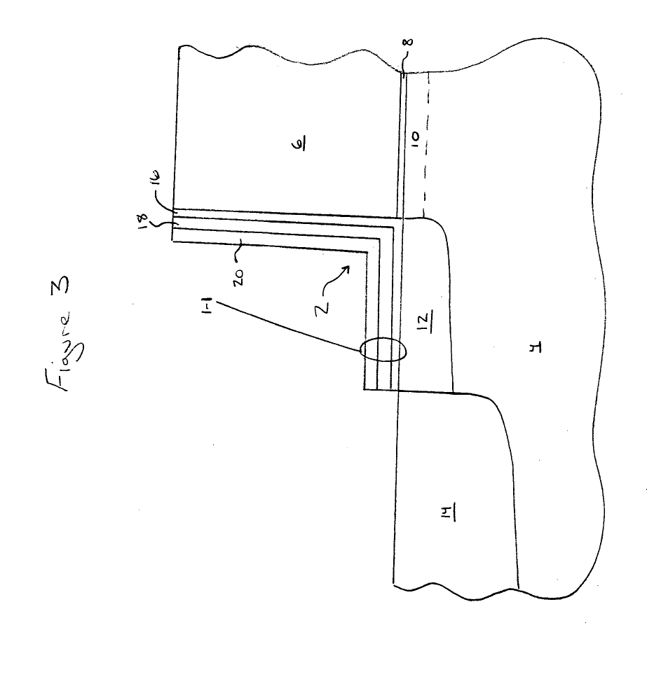

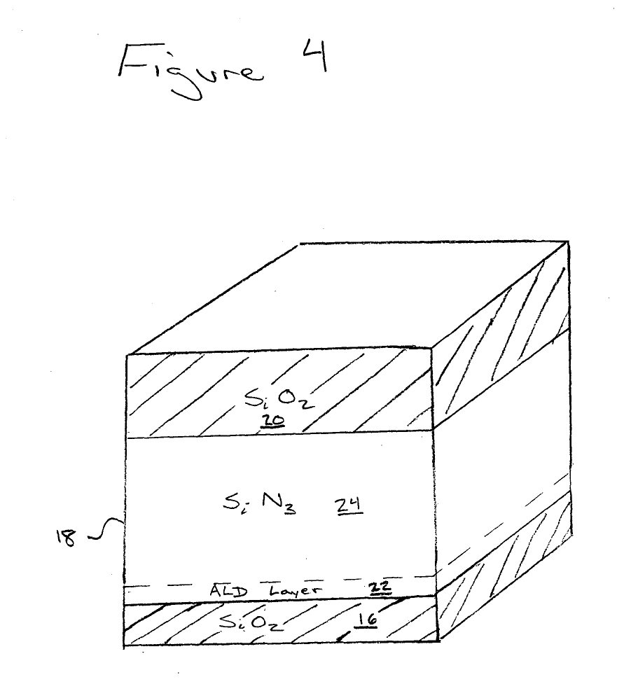

Referring to the Figures by characters of reference, FIG. 3 illustrates a view of a Metal Oxide Semiconductor Field Effect Transistor (MOSFET) having an Oxide-Nitride-Oxide spacer 2 fabricated in accordance with a preferred embodiment of the present invention. Spacer 2 is a multilayered dielectric stack structure fabricated on wafer 4. The present invention provides a novel structure and method for fabricating the nitride layer formed within Oxide-Nitride-Oxide spacer 2, which is illustrated in FIGS. 4-11. Spacer 2 abuts the lateral side of a gate structure 6.

Gate electrode structure 6 is fabricated over a gate dielectric layer 8. Typically, dielectric layer 8 is an oxide. Together, gate structure 6, dielectric layer 8, and wafer 4 form a Metal Oxide Semiconductor (MOS) capacitor. Operation of this MOS capacitor regulates a channel 10 that extends underneath dielectric layer 8 where current flows between the source and drain LDD regions 12 and contact regions 14 of the MOSFET.

The MOSFET illustrated in FIG. 3 is a Lightly Doped Drain (LDD) MOSFET. LDD MOSFETS are fabricated having a shallow source/drain implant region 12 that extends between channel 10 and the more heavily doped source/drain contact regions 14. In an LDD MOSFET, shallow source/drain extensions 12 aid in minimizing hot carrier effects. Scaling reductions in MOSFET sizes has brought source/drain regions 12 and gate 6 contacts sufficiently close together such that ballistic transport can occur through channel 10. The reduced doping gradient provided by lightly doped source/drain extensions 12 in going between source/drain contacts 14 across channel 10 lowers the electric field in the vicinity of the drain and shifts the position of the peak electric field toward the end of channel 10. Carrier injection into dielectric layer 8 is thereby reduced.

Spacer 2 extends over these source/drain regions 12. In LDD MOSFETS, spacers 2 serve a variety of functions. Spacer 2 masks the lightly doped source drain regions 12 from the fabrication process that is used to create heavily doped source/drain contact regions 14. Heavily doped source/drain contact regions 14 are formed using a heavy implant process that is blocked from affecting lightly doped regions 12 by spacers 2. Consequently, the width, w, of spacer 2 determines the width of the lightly doped source/drain regions 12. The width, w, of lightly doped source/drain regions 12 affects the operating parameters of the MOSFET, including the parasitic resistance. Therefore, through varying the width, w, of spacers 2, it is possible to vary the width of the lightly doped source-drain regions and in doing so, control the value of the parasitic resistance in the MOSFET.

Spacer 2 also functions to provide electrical isolation for gate structure 6 from the source and drain contacts of the MOSFET, thereby increasing device performance. In addition, spacer 2 electrically pacifies the sidewalls of gate stack 6. In the present invention, spacer 2 is formed in an “L” configuration. Alternate configurations for spacer 2 include a “D” configuration, trapezoidal, and triangular configuration.

The general structure of spacer 2 is that of an Oxide-Nitride-Oxide (ONO) spacer. The ONO structure of spacer 2 is formed with an initial deposition of a thin conformal oxide layer 16, referred to as first oxide layer 16, over wafer 4 and gate electrode 6. First oxide layer 16 functions to isolate silicon nitride (Si₃N₄) layer 18 from the Si surface of wafer 4. SiN/Si interfaces have stress that degrades device properties. First oxide layer 16 is provided to avoid the introduction of this stress by separating silicon nitride (Si₃N₄) layer 18 from the Si surface of wafer 4.

Silicon nitride (Si₃N₄) 18 layer is formed over first oxide layer 16 to function as an etch stop. Silicon nitride (Si₃N₄) has a very high selectivity ratio with respect to SiO₂. Therefore, with silicon nitride (Si₃N₄) layer 18, it is possible to vary the width, w, of spacer 2 independently of the height, h, of spacer 2. Consequently, it is possible to vary the width, w, of source/drain extensions 12 in order to accommodate scaling demands for shorter LDD region widths 12 that are possible with shallow diffusion techniques. A second oxide layer 20 is deposited over nitride layer 18 to complete formation of ONO spacer 2.

Spacer 2 of the present invention includes a nitride layer 18 formed with a novel spacer deposition sequence that protects underlying first oxide layer 16 from nitridization. Inhibiting the nitridization of underlying first oxide layer 16 is facilitated through providing a process for nitride deposition that does not expose first oxide layer 16 to ammonium (NH₃) precursors. Consequently, with the present invention, it is possible to fabricate ONO spacer structures that do not suffer from stressed interfaces, clusterization, and degradation of the drive current that are caused by nitridization of first oxide layer 16 from ammonium precursors.

Typically, nitride layer 18 is formed through a conventional silicon nitride (Si₃N₄) plasma process that can include ammonium precursors. The chemical formula for fabricating nitride layer 18 with ammonium precursors is given by Formula 1 below:
3Si (solid)+4NH₃ (gas)→Si₃N₄ (solid)+6H₂ (gas) Formula 1
Conventional thermal silicon nitride (Si₃N₄) plasma processes that include ammonium precursors can nitridize oxide layers, such as layer 16, if the oxide layers are exposed to the ammonium precursors. Nitridization of oxide layers converts the layer to oxynitride as given by Formula 2 below:
2SiO₂+2NH₃→Si₂ON₂+3H₂O Formula 2

This nitridized oxide film 16 causes stress at the silicon-oxynitride interface, as well as at the “corner” of the gate oxide adjacent to the spacer oxide 16. The stress at the gate corner region is a feature size stress. The stress located in the gate region can cause degradation of device performance parameters. The stress at the silicon-oxynitride interface is an atomic scale of stress. The width, w, of spacer 2 determines the depth of stress penetration into substrate 4. The stressed interface at the LLD regions 12 results in the deactivation of acceptors or donors in source/drain regions 12 via a clustering mechanism. This deactivation causes a higher series resistance in the source/drain extensions 12 and degrades the drive current. One method of accounting for the deactivation of dopants is through increasing the dopant dose in advance. However, this compensation through a higher dopant dose results in an increase in the depth of the LDD extensions 12. Ultimately, this compensation leads to deterioration of the MOSFET device performance due to Short Channel Effects (SCE). In addition, the stress at the LLD region can result in further degradation in device properties via a junction leakage mechanism.

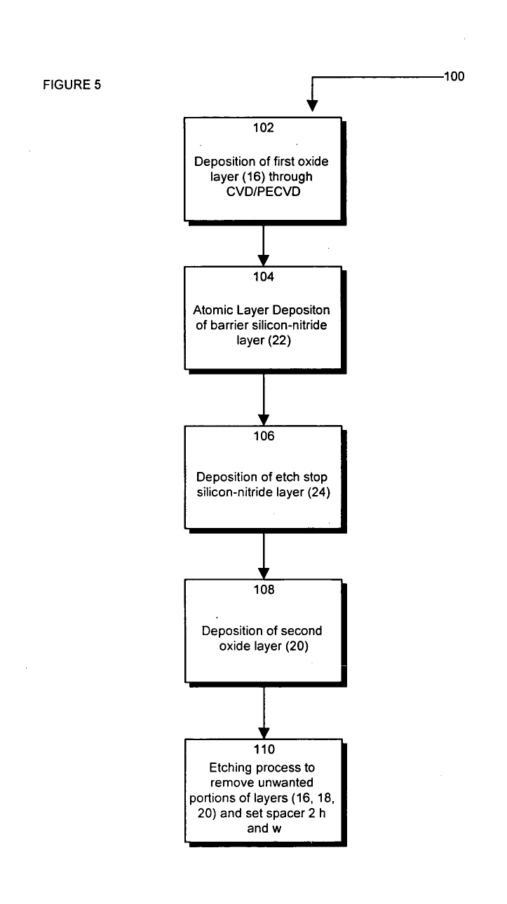

Referring again to FIG. 3, the circled portion of spacer 2, designated as 1-1, identifies a cross-section of the spacer stack that forms spacer 2. The spacer stack is a stack of layered materials, which form spacer 2. The present invention provides a novel structure and method for fabricating silicon nitride (Si₃N₄) layer 18 within the spacer stack to inhibit the nitridization of oxide layer 16 and avoid the problems associated with nitridization. Preferred and alternate embodiments of the present invention for the novel spacer stacks that form spacer 2 are illustrated in FIGS. 4, 6, 8, and 10. Processes for forming the preferred and alternate embodiments of the spacer stacks of the present invention are illustrated in FIGS. 5, 7, 9, and 11 respectively.

FIG. 4 illustrates a cross-section of a spacer stack that forms spacer 2 fabricated in accordance with a preferred embodiment of the present invention. The spacer stack of FIG. 4 has an ONO structure. The base layer of spacer stack is an oxide layer 16 that is deposited over wafer 4. A silicon nitride (Si₃N₄) layer 18 is deposited over oxide layer 16. SiN/Si interfaces have a high level of stress that leads to degradation of device performance. Through providing oxide layer 16 between silicon nitride (Si₃N₄) layer 18 and Si wafer 4, the creation of a SiN/Si interface is prevented and introduction of this stress is avoided. A second oxide layer 20 is then deposited over silicon nitride (Si₃N₄) layer to complete the ONO structure.

In accordance with a preferred embodiment of the present invention, a novel structure and process for fabrication of silicon nitride (Si₃N₄) layer 18 is provided to avoid nitridization of oxide layer 16, thereby enhancing device performance. Silicon nitride (Si₃N₄) layer 18 is fabricated through a process that does not expose oxide layer 16 to ammonium precursors, thereby preventing its nitridization. A barrier layer of nitride 22 is deposited over oxide layer 16 through an Atomic Layer Deposition (ALD) process. This ALD process does not include the use of ammonium precursors. Since ammonium precursors are not used to deposit barrier layer of nitride 22, oxide layer 16 is not nitridized during this process.

An etch stop layer of nitride 24 is deposited over barrier layer of nitride 22 through a conventional deposition process that includes the use of ammonium precursors. Etch stop layer of nitride 24 is formed in order to provide a barrier to the etching process used to shape spacer 2. Due to the presence of barrier layer of nitride 22, oxide layer 16 is not exposed to the ammonium precursors used to form etch stop layer of nitride 24 since ammonium precursors cannot easily diffuse through nitride. An exemplary thickness for barrier nitride layer 22 is 1.5 to 3.0 nm. An exemplary thickness for etch stop layer 24 is 30 to 90 nm.

Barrier silicon nitride (Si₃N₄) layer 22 functions as barrier protecting oxide layer 16 from the ammonium precursors present in the plasma process that forms layer 24 as given by Formula 1. Barrier silicon nitride (Si₃N₄) layer 22 is formed through a nitride deposition process that does not include the presence of ammonium precursors. Consequently, the deposition of barrier silicon nitride (Si₃N₄) layer 22 does not nitridize first oxide layer 16. Once barrier silicon nitride (Si₃N₄) layer 2 is deposited, subsequent deposition of layer 24 with ammonium precursors can occur. Barrier silicon nitride (Si₃N₄) layer 22 blocks the ammonium precursors used in the process to deposit layer 24 from interacting with and nitridizing oxide layer 16. Through inhibiting formation of a silicon-oxynitride interface, barrier silicon nitride (Si₃N₄) layer 22 deters formation of interface stresses that cause deactivation of acceptors or donors in source/drain regions 12 via the clustering mechanism. Consequently, this structure having barrier silicon nitride (Si₃N₄) layer 22 facilitates the inclusion of nitride layer 18 with spacer 2 without causing higher series resistance in source/drain extensions 12 and without degradation of the drive current.

When compared to conventional nitride deposition processes that include ammonium precursors, ALD processes take longer periods of time to complete and are more expensive. It is therefore desirable to continue to utilize conventional nitride deposition processes to form the relatively thick 30 to 90 nm etch stop layer of nitride 24 after formation of the initial barrier nitride layer 22.

Through formation of barrier nitride layer 22 and etch stop nitride layer 24, it is possible to fabricate a silicon nitride (Si₃N₄) layer 18 that utilizes cost effective nitride deposition techniques without nitridizing oxide layer 16, thereby enhancing the device performance.

FIG. 5 illustrates a flow chart 100 depicting a process for fabricating spacer stack illustrated in FIG. 4. In step 102, first spacer oxide layer 16 is deposited through a conventional CVD or PECVD process. In the process illustrated by FIG. 5, nitride layer 18 is formed through a two-step process. In step 104, barrier silicon nitride (Si₃N₄) layer 22 is deposited over first oxide layer 16. A preferred method of fabricating barrier silicon nitride (Si₃N₄) layer 22 is through an Atomic Layer Deposition (ALD) process. An exemplary thickness for barrier silicon nitride (Si₃N₄) layer 22 is 1.5 nm to 3 nm.

After the fabrication of barrier silicon nitride layer 22 in step 104, the process proceeds to step 106 where etch stop silicon nitride layer 24 is deposited. It is possible to form etch stop silicon nitride layer 24 through a variety of processes, including conventional CVD type deposition processes using ammonium precursors. In step 108, second spacer oxide 20 is deposited over etch stop silicon nitride layer 24 through either a CVD or PECVD process. Finally in step 110, an etching process is used to remove unwanted portions of layers 16, 18, and 20 deposited in the previous steps in order to fabricate spacer 2 with a desired width, w, and a height h.

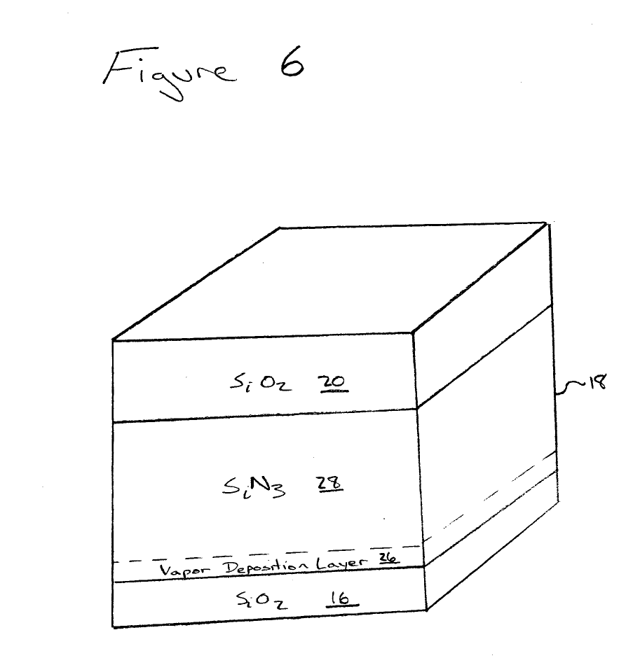

FIG. 6 illustrates a cross-section of a spacer stack fabricated for spacer 2 in accordance with an alternative embodiment of the present invention. The spacer stack of FIG. 6 includes nitride layer 18 formed between two oxide layers 16 and 20, thereby froming an ONO structure. Nitride layer 18 is formed from a barrier nitride layer 26 and an etch stop layer of nitride 28. In this alternative embodiment of the invention, barrier nitride layer 26 is formed through a Plasma Enhanced Chemical Vapor Deposition (PECVD) process utilizing N₂ and SiCl₄ or SiF₄ or other H-free Si-carrying precursors. Another way of forming barrier nitride layer 26 in this embodiment is through Jet Vapor Deposition (JVD) or N—Si-radical contained in organic precursors, e.g. tertiary-butyl amino silane (BTBAS). Since ammonium precursors are not used to form barrier nitride layer 26, oxide layer 16 is not nitridized. Subsequent deposition of etch stop layer of nitride 28 through conventional nitride deposition processes that include ammonium precursors are then possible due to the fact that barrier nitride layer 26 blocks the ammonium precursors from reaching oxide layer 16. Therefore, as with the preferred embodiment, this alternative embodiment facilitates the use of conventional deposition processes to form the relatively thick nitride etch stop layer 28 without exposing oxide layer 16 to nitridization through the formation of barrier nitride layer 26.

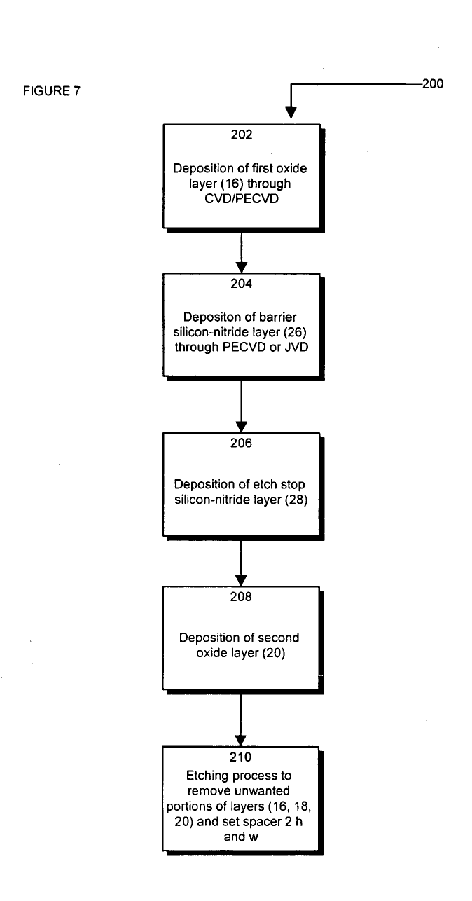

FIG. 7 illustrates a flow chart 200 depicting a process for fabricating the spacer stack illustrated in FIG. 6. In step 202, first spacer oxide layer 16 is deposited through a conventional CVD or PECVD process. In the process illustrated by FIG. 7, nitride layer 18 is formed through a two-step process. In step 104, barrier silicon nitride (Si₃N₄) layer 26 is deposited over first oxide layer 16. One method of fabricating barrier silicon nitride (Si₃N₄) layer 26 as illustrated in FIG. 6 is through a Plasma Enhanced Chemical Vapor Deposition (PECVD) process utilizing N₂ and SiCl₄ or SiF₄ components without ammonium precursors. Another way of forming barrier nitride layer 26 in this embodiment is through Jet Vapor Deposition (JVD) or N—Si-radical containing in an organic precursors, e.g. tertiary-butyl amino silane (BTBAS). An exemplary thickness for barrier silicon nitride (Si₃N₄) layer 26 is 1.5 nm to 10 nm or even up to the total Si₃N₄ thickness if a process is optimized to provide a good Si₃N₄ quality and a practical rate of deposition.

After the fabrication of barrier silicon nitride (Si₃N₄) layer 26 in step 204, the process proceeds to step 206 where etch stop silicon nitride (Si₃N₄) layer 24 is deposited. It is possible to form etch stop silicon nitride (Si₃N₄) layer 24 through a variety of processes, including conventional CVD type deposition processes using ammonium precursors. In step 208, second oxide layer 20 is deposited over etch stop silicon nitride (Si₃N₄) layer 28 through either a CVD or PECVD process. Finally in step 210, an etching process is used to remove unwanted portions of layers 16, 18, and 20 deposited in the previous steps in order to fabricate spacer 2 with a width, w, and a height h. Since ammonium precursors are not used to form barrier nitride layer 26, oxide layer 16 is not nitridized. Subsequent deposition of etch stop layer of nitride 28 through conventional nitride deposition processes that include ammonium precursors are then possible due to the fact that barrier nitride layer 26 blocks the ammonium precursors from reaching oxide layer 16. If the total Si₃N₄ thickness can be done by the first step, the second step can be omitted to simplify the process.

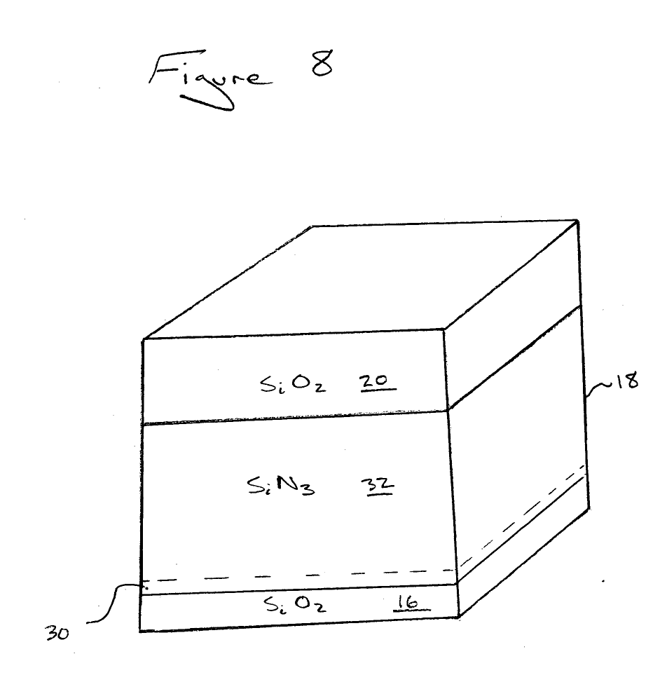

FIG. 8 illustrates a cross-section of a spacer stack fabricated in accordance with an alternative embodiment of the present invention. In this alternative embodiment of the invention, nitride layer 18 also includes a barrier nitride layer 30 and a nitride etch stop layer 32. Barrier nitride layer 30 is formed through an initial deposition of a thin silicon layer 30 of 1 to 2 nm of amorphous, or poly-silicon using ALD, JVD, or other processes that allow for such deposition of very thin layers. This layer 30 of amorphous, or poly-silicon is then nitridized through a plasma process. The nitridization of amorphous Si is a self-limiting process because the nitridization precursors are limited by diffusion through the ever-increasing thickness of the converted nitride layer. Therefore, no contamination, i.e. formation of oxynitride, in the underlying oxide can occur. This alternative embodiment for the formation of a spacer structure with barrier nitride layer 30 formed with nitridized amorphous, or poly-silicon allows for the formation of an ONO structure without the nitridization of oxide layer 16. Conventional nitride deposition processes deposit second nitride layer 32. These plasma processes can include ammonium precursors, thereby making formation of barrier nitride layer 30 and nitride etch stop layer 32 relatively fast and economical.

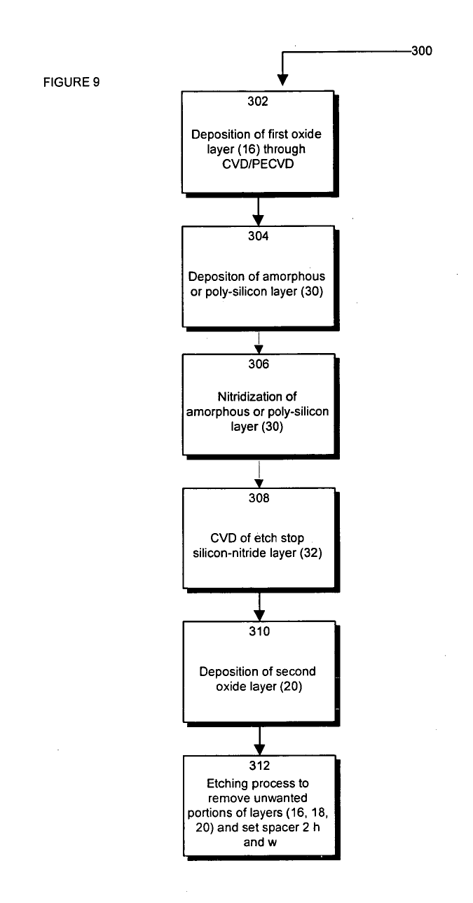

FIG. 9 illustrates a flow chart 300 depicting a process for fabricating the spacer stack illustrated in FIG. 8. In step 302, first spacer oxide layer 16 is deposited through a conventional CVD or PECVD process. In the process illustrated by FIG. 9, nitride layer 18 is formed through a two-step process. The method of fabricating barrier silicon nitride (Si₃N₄) layer 18 as illustrated in FIG. 8 is through an initial deposition of a layer 30 of 1 to 2 nm of amorphous, or poly-silicon in step 304. In step 306, this layer 30 of amorphous, or poly-silicon is then nitridized through a plasma process. A second process 308 is used to deposit the final etch stop nitride layer 32. With this second process in step 310, second spacer oxide 20 is deposited over etch stop silicon nitride (Si₃N₄) layer 32 through either a CVD or PECVD process. Finally in step 312, an etching process is used to remove unwanted portions of the layers 16, 18, and 20 deposited in the previous steps in order to fabricate spacer 2 with a width, w, and a height h. Since nitridization is a self-limiting process, the ammonium precursors used in the plasma process to convert amorphous, or poly-silicon Si layer 30 into the nitride barrier layer 30, are prevented from nitridizing the oxide layer 16, since they are unable to penetrate the nitride layer as it is formed in the diffusion limited process. Therefore, an ONO spacer 2 is fabricated that does not suffer from the ill effects caused by nitridization of oxide layer 16.

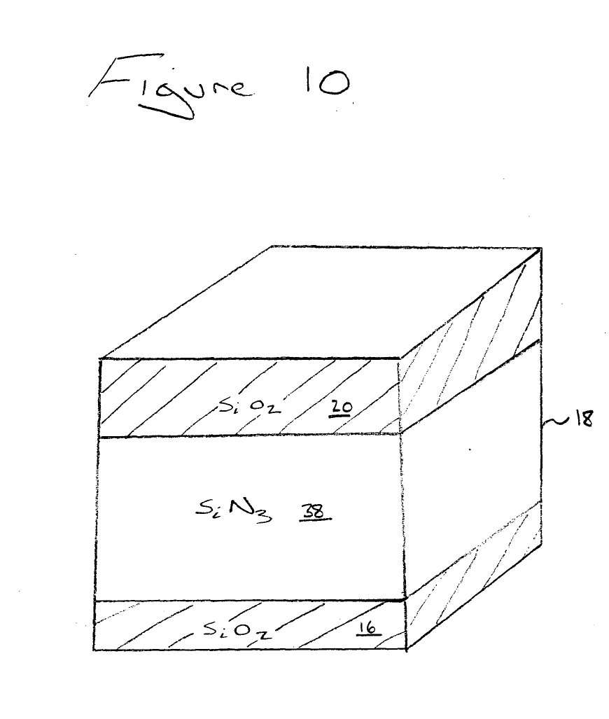

FIG. 10 illustrates a cross-section of a spacer stack fabricated in accordance with an alternative embodiment of the present invention. In this alternative embodiment, the spacer stack is formed having a silicon nitride (Si₃N₄) layer 18/38 formed through a single ALD process. The entire thickness of silicon nitride (Si₃N₄) layer 18/38 is formed through deposition of nitride through the ALD process. Since deposition of nitride with ALD does not utilize ammonium precursors, oxide layer 16 is not nitridized.

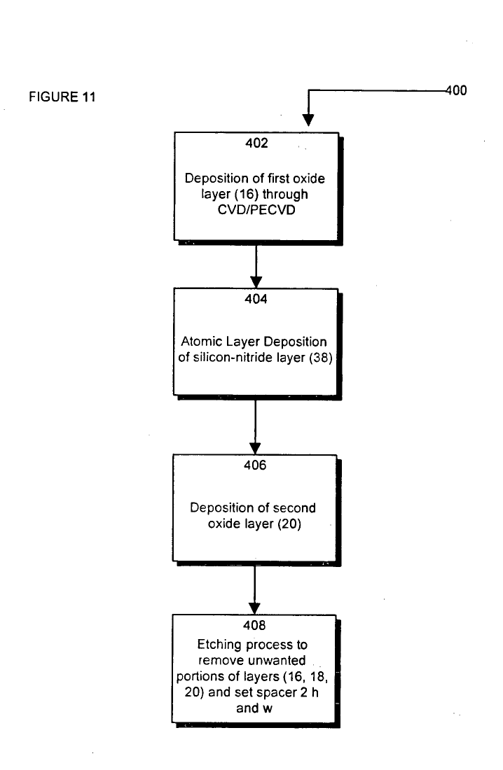

FIG. 11 illustrates a flow chart 400 depicting a process for fabricating the spacer stack illustrated in FIG. 10. In step 402, first oxide layer 16 is deposited through a conventional CVD or PECVD process. In step 404, silicon nitride (Si₃N₄) layer 18/38 is deposited over first oxide layer 16. The method of fabricating first silicon nitride (Si₃N₄) layer 18/38 as illustrated in FIG. 10 is through an Atomic Layer Deposition of silicon nitride (Si₃N₄) that does not include the use of ammonium precursors. An exemplary thickness for first silicon nitride (Si₃N₄) layer 18/38 is 30 nm to 90 nm. Note that in this process, the entire nitride layer 18/38 is formed through a single process.

After the fabrication of silicon nitride (Si₃N₄) layer 18/38 in step 404, the process proceeds to step 306 where second oxide layer 20 is deposited over silicon nitride (Si₃N₄) layer 18/38 through either a CVD or PECVD process. Finally in step 406, an etching process is used to remove unwanted portions of the layers 16, 18, and 20 deposited in the previous steps in order to fabricate spacer 2 with a width, w, and a height h. Since ammonium precursors are not used to form nitride layer 18/38, oxide layer 16 is not nitridized.

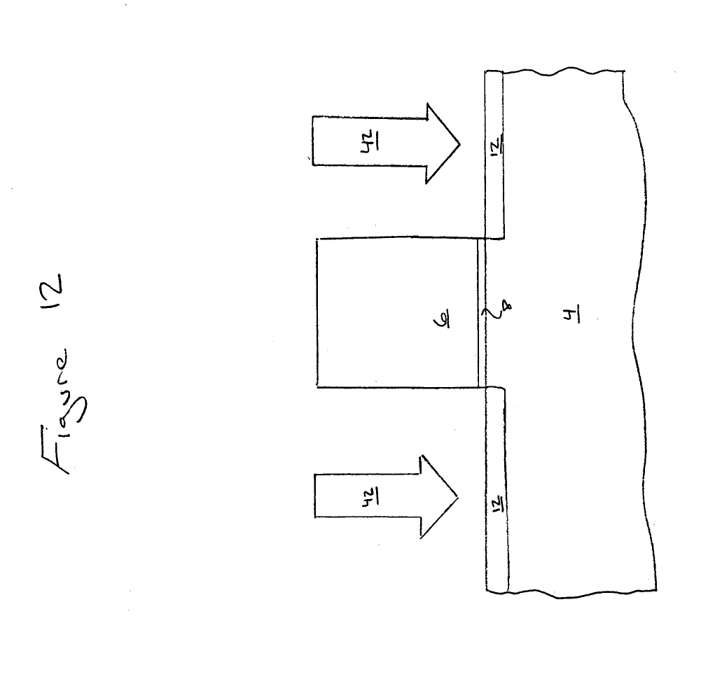

FIGS. 12-16 illustrate a series of diagrams depicting a preferred process for fabricating spacer 2 in accordance with a present preferred embodiment of the invention.

FIG. 12 illustrates an initial fabrication stage where a gate structure 6 is formed over a gate dielectric layer 8 on top of a wafer 4. Dielectric layer 8 is typically formed from silicon dioxide. Exemplary materials for the electrode in gate structure 6 are polysilicon and metal. At this stage, as illustrated in FIG. 3, lightly doped source/drain extensions 12 are formed using a light implant process 42.

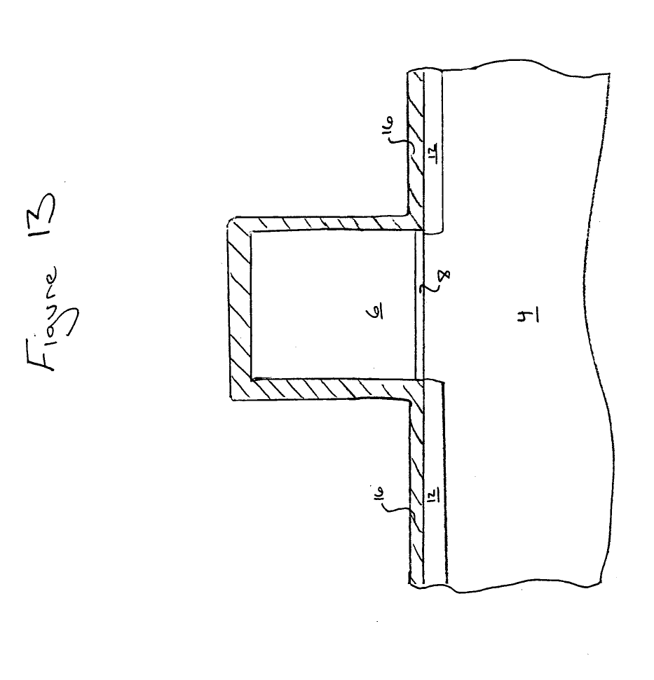

FIG. 13 illustrates fabrication of first oxide layer 16 on to wafer 4. It is possible to form first oxide layer 16 from a variety of deposition processes including Chemical Vapor Deposition (CVD) and Plasma Enhanced Chemical Vapor Deposition (PECVD). An exemplary material for first spacer oxide layer 16 is TEOS (Tetraethoxysilane). TEOS is a gaseous compound commonly used in CVD SiO₂ processes that conforms well to the underlying surface.

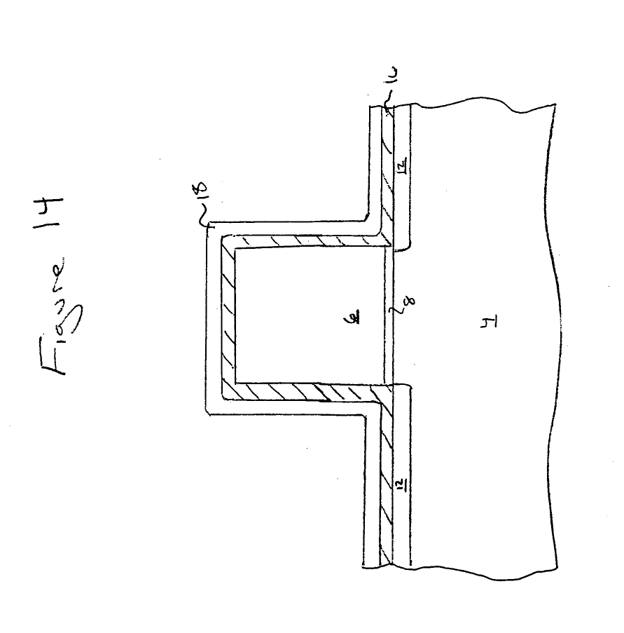

FIG. 14 illustrates a diagram of a semiconductor wafer 4 having silicon nitride (SiN) layer 18 deposited over first spacer oxide layer 16 in accordance with a present embodiment of the invention as described in FIGS. 4-11. Silicon nitride (Si₃N₄) layer 18 provides a protective layer for first oxide layer 16 to guard against nitridization by fabrication processes that involve the use of ammonium precursors.

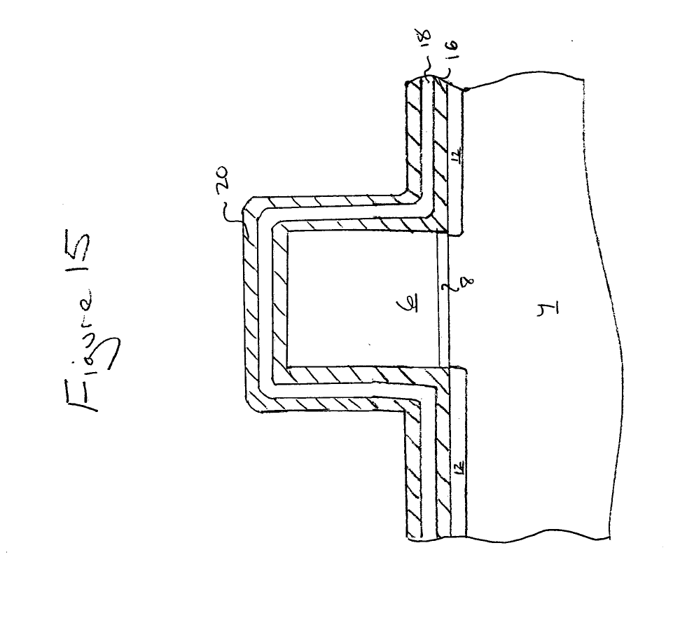

FIG. 15 illustrates a diagram of semiconductor wafer 4 having second oxide layer 20 deposited over second silicon nitride (SiN) layer 18 accordance with a present preferred embodiment of the invention. Second oxide layer 20 is deposited through a conventional CVD or PECVD process.

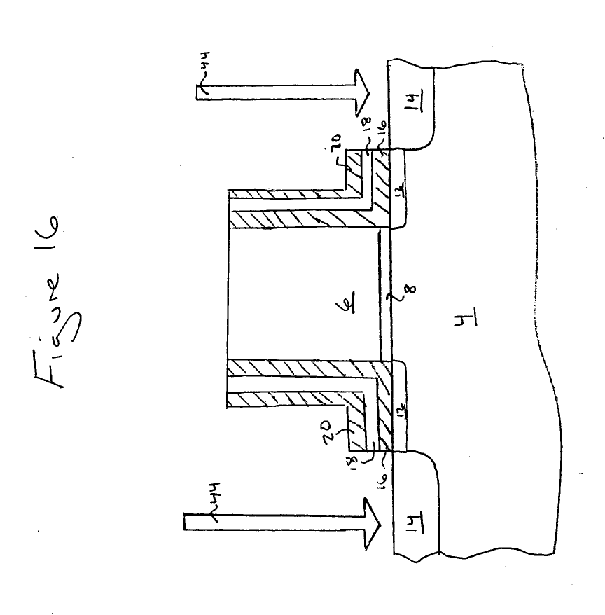

FIG. 16 illustrates a diagram of a cross-section of semiconductor wafer 4 having spacer 2 formed in accordance with a present preferred embodiment of the invention. At this stage of fabrication, etching processes are used in order to form spacers 2 with a desired width, w, and height, h. The width, w, of spacers 2 determines the width, w, of lightly doped regions 12. A subsequent heavy implant process 44 is then used in order to create source/drain contact regions 14.

Having fully described the invention with referred to the preferred embodiments illustrated in the attached drawing Figures, it will be really appreciated by those skilled in the art that many changes and modifications may be made to the invention without departing from the essence of the invention and without being included within the spirit and scope of the invention as is defined by the appended claims.

1. A dielectric spacer structure, comprising:
a first oxide layer deposited over a top surface of a wafer and abutting a gate structure;
a silicon-nitride barrier layer deposited over said first oxide layer, wherein said silicon-nitride barrier layer is formed without exposing said first oxide layer to a chemical component that nitridizes SiO₂ and Si-SiO₂ interfaces, thereby enabling formation of said silicon nitride barrier layer without nitridizing said first oxide layer; and
a second oxide layer formed over said silicon-nitride barrier layer.

2. The dielectric spacer structure of claim 1, further comprising an etch stop nitride layer formed between said silicon-nitride barrier layer and said second oxide layer, wherein said etch stop nitride layer is formed through a process that includes ammonium precursors.

3. The dielectric spacer structure of claim 1, wherein said silicon nitride barrier layer is formed through an atomic layer deposition process.

4. The dielectric spacer structure of claim 1, wherein said silicon nitride barrier layer is formed through an atomic layer deposition of silicon that is nitridized by a plasma process.

5. The dielectric spacer structure of claim 1, wherein said silicon nitride barrier layer is formed through vapor deposition of a nitrogen-silicon gas containing a non-ammonia based organic precursor.

6. The dielectric spacer structure of claim 1, wherein said silicon-nitride barrier layer is formed from vapor deposition of N₂ and SiCl₄.

7. The dielectric spacer structure of claim 1, wherein said silicon-nitride barrier layer is formed from vapor deposition of N₂ and SiF₄.

8. The dielectric spacer structure of claim 2, wherein said silicon-nitride barrier layer has a thickness of 1.5 to 3.0 nm and said etch stop nitride layer has a thickness of 30 nm to 90 nm.

9. The dielectric spacer structure of claim 3, wherein said silicon-nitride barrier layer has a thickness of 30 nm to 90 nm.

10. A spacer, comprising:
a first spacer oxide layer abutting a gate structure of a MOSFET;
a silicon-nitride layer formed over said first spacer oxide layer, wherein said silicon-nitride layer includes barrier means to inhibit ammonium precursors from reaching and interacting with said first spacer oxide layer, thereby protecting said first spacer oxide layer from nitridization by said ammonium precursors; and
a second spacer oxide layer formed over said silicon nitride layer.

11. The spacer of claim 10, wherein said barrier means is formed through deposition means that create a nitride barrier layer without nitridizing said first spacer oxide layer.

12. The spacer of claim 10, wherein said barrier means is formed from a layer of nitridized silicon.

13. The spacer of claim 10, wherein said silicon-nitride layer has a thickness of 30 nm to 90 nm, wherein 1.5 nm to 3.0 nm of said silicon-nitride layer forms said barrier means.

14. The dielectric spacer structure of claim 10, wherein said barrier means blocks diffusion of ammonium precursors into said first spacer oxide layer.

15. A spacer stack, comprising:
a first oxide spacer layer free of nitridization that abuts a MOSFET gate electrode;
a silicon-nitride layer formed over said dielectric layer; and
a second oxide spacer layer formed over said silicon-nitride layer.

16. The spacer stack of claim 15, wherein said spacer structure includes a barrier layer formed between said silicon-nitride layer and said first oxide spacer layer.

17. The spacer stack of claim 16, wherein said barrier layer is formed of silicon-nitride having a thickness of 1.5 nm to 3.0 nm.

18. The spacer stack of claim 17, wherein said barrier layer is formed through atomic layer deposition.

19. The spacer stack of claim 17, wherein said barrier layer is formed through vapor deposition of silicon-nitride.

20. The spacer stack of claim 17, wherein said barrier layer is formed through nitridization of a silicon layer that is deposited between said silicon-nitride layer and said first spacer oxide layer.
